(19) United States
(12) Patent Application Publication
(10) Pub. No.: US 2022/0108918 A1
(43) Pub. Date: Apr. 7, 2022

(54) DRY ETCH BACK SUBSTRATE INTERCONNECTIONS

(71) Applicant: QUALCOMM Incorporated, San Diego, CA (US)

(72) Inventors: Kuiwon KANG, San Diego, CA (US); Joan Rey Villarba BUOT, Escondido, CA (US); Jialing TONG, San Diego, CA (US)

(21) Appl. No.: 17/064,471

(22) Filed: Oct. 6, 2020

(51) Int. Cl. H01L 21/768; H01L 21/3213; C25D 3/56; H01L 23/528; H01L 23/00

(52) U.S. Cl. CPC H01L 21/76879; H01L 21/32131; C25D 3/56; H01L 2224/04042; H01L 24/05; H01L 24/03; H01L 23/528

(57) ABSTRACT

A method of forming electrical interconnections comprises patterning a trace on a dielectric layer and then masking the dielectric layer for plating. The dielectric layer is plated to form electrical interconnections. After plating the masking is removed. A laser etch back of the trace is performed after removing the masking, in which the laser etch back removes tails on the trace. After the laser etch back, the patterned traces and the dielectric layer are cleaned.

### FIELD OF THE DISCLOSURE

Aspects of the present disclosure relate to integrated circuits, and more particularly to techniques and apparatuses for dry etch back of substrate interconnections for semiconductor devices.

### BACKGROUND

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile devices demand a small form factor, low cost, a tight power budget, and high electrical performance. Mobile packaging design has evolved to meet these divergent goals for enabling mobile applications that support multimedia enhancement. Fabrication of these mobile application devices, however, is susceptible to long tails or traces, where a desired interconnect exceeds a design length. There exists a need for further improvements in semiconductor fabrication to obtain improved electrical interconnections with less insertion loss, reflection loss, and cross talk noise. These improved semiconductor devices may have applicability to fifth generation (5G) new radio (NR) wireless communication devices.

Semiconductor devices are fabricated with both wire bond and surface mount device (SMD) pads. Both interconnection types are formed with plating lines when the electrical interconnections are formed. These interconnections may be formed with a nickel (Ni)/gold (Au) plating process that can leave a long tail or trace after chemical etch back to remove excess plated material. The long tails or long traces can exceed the design length for the interconnection. The long tails can adversely affect electrical performance with insertion loss, reflection loss, and cross talk noise during operation of the completed semiconductor device. As the demands for 5G NR devices increase, there becomes a need to ensure optimum electrical performance of those devices and to improve manufacturing processes to provide traces that meet electrical specifications.

### SUMMARY

An aspect of the disclosure provides a method of forming electrical interconnections. The method comprises patterning a trace on a dielectric layer and masking the dielectric layer for plating. The method continues with plating the dielectric layer to form electrical interconnections and then removing the masking after plating. A laser etch back of the trace is performed after removing the masking. The laser etch back removes tails on the trace. The method concludes with cleaning the patterned traces and the dielectric layer after performing the laser etch back.

A further aspect of the present disclosure includes an electronic device. The electronic device includes a dielectric layer having a trace patterned on the dielectric layer. The electronic device also includes a plating material on the trace electrically coupled to the trace and a long tail extending from the trace, and configured to be laser etched back based on length.

A still further aspect provides an electrical interconnection. The electrical interconnection comprises a dielectric layer having a trace patterned on the dielectric layer. The trace is configured to form an electrical interconnection. The electrical interconnection also comprises means for forming electrical interconnections with the trace and a long tail extending from the trace and configured to be laser etched back based on length.

Aspects generally include a method, apparatus, system, computer program product, non-transitory computer-readable medium, user equipment, base station, wireless communications device, and processing system as substantially described with reference to and as illustrated by the accompanying drawings and specification.

The foregoing has outlined rather broadly the features and technical advantages of examples according to the disclosure in order that the detailed description that follows may be better understood. Additional features and advantages will be described. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only certain aspects of this disclosure and are therefore not to be considered limiting of its scope, for the description may admit to other equally effective aspects. The same reference numbers in different drawings may identify the same or similar elements.

FIG. 1 illustrates an example implementation of a system-on-a-chip (SoC), including dry etch back substrate interconnections, in accordance with certain aspects of the present disclosure.

FIG. 2 shows a cross-sectional view of a stacked integrated circuit (IC) package, including the system-on-a-chip (SoC) of FIG. 1.

FIG. 3 shows a cross-sectional view illustrating the integrated circuit (IC) package of FIG. 2, incorporated into a mobile device, according to one aspect of the present disclosure.

FIG. 4A shows a top view of a wire bond trace before laser etching, in accordance with various aspects of the present disclosure.

FIG. 4B shows a top view of a wire bond trace after laser etching, in accordance with various aspects of the present disclosure.

FIG. 4C shows a side view of a wire bond trace after laser etching, in accordance with various aspects of the present disclosure.

FIG. 5A shows a top view of a surface mount device (SMD) pad trace before laser etching, in accordance with various aspects of the present disclosure.

FIG. 5B shows a top view of a surface mount device (SMD) pad trace after laser etching, in accordance with various aspects of the present disclosure.

FIG. 5C shows a side view of a surface mount device (SMD) pad trace after laser etching, in accordance with various aspects of the present disclosure.

FIGS. 6A-6G are cross-sectional diagrams illustrating a manufacturing process flow for a wire bond trace, in accordance with aspects of the present disclosure.

FIGS. 7A-7D are cross-sectional diagrams illustrating a manufacturing process flow for a surface mount device (SMD) pad trace, in accordance with aspects of the present disclosure.

FIG. 8 shows a top view of a logic die and a memory package, incorporating a reduction in path length, in accordance with various aspects of the present disclosure.

FIG. 9 is a flow diagram of a process for laser etching a wire bond trace, in accordance with aspects of the present disclosure.

FIG. 10 is a flow diagram of a process for laser etching a surface mount device (SMD) pad trace, in accordance with aspects of the present disclosure.

FIG. 11 is a block diagram showing an exemplary wireless communications system in which a configuration of the disclosure may be advantageously employed.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations.

A system hierarchy includes interconnection of active devices at a lowest system level all the way up to system level interconnections at a highest level. In particular, electrical connections exist at each of the levels of the system hierarchy to connect different devices together on an integrated circuit (IC). As ICs become more complex, however, more interconnect layers are used to provide the electrical connections between the devices. More recently, the number of interconnect levels for circuitry has substantially increased due to the large number of devices that are now interconnected in a state-of-the-art mobile application device.

Wireless devices rely on semiconductor devices, which may be referred to as system-on-a-chip (SoC) devices, to perform the signal processing for wireless communications, such as 5G communications. Semiconductor fabrication is a multiple-step sequence of photolithographic and chemical processing steps (such as surface passivation, thermal oxidation, planar diffusion, and junction isolation) that gradually create electronic circuits on a wafer made of a semiconducting material.

The process steps for semiconductor fabrication often include deposition, removal, patterning, and modification of electrical properties. Deposition grows, coats, or transfers a material onto the wafer. Deposition may be performed by physical vapor deposition, chemical vapor deposition, electrochemical deposition, molecular beam epitaxy, and atomic layer deposition. Deposition includes oxide layer formation by thermal oxidation.

After deposition, a removal process removes material from the wafer using an etch process to begin to form interconnections or traces. Removal processes may use wet or dry etching and chemical-mechanical planarization. Patterning is the shaping or altering of deposited material and is known as lithography. In conventional lithography, the wafer is coated with a chemical called photoresist, then a stepper focuses, aligns, and removes a mask, exposing select portions of the wafer to short wavelength light. The exposed regions are then washed away by a developer solution. After etching, any remaining photoresist is removed by plasma ashing.

At this point, modification of the electrical properties begins with doping transistor sources and drains. Doping is followed by furnace annealing or by rapid thermal annealing. Annealing activates the implanted dopants. Modification of the electrical properties at this point in the fabrication process may occur by exposing selected sections of the wafer to ultraviolet light. Modification may also result from oxidation, useful for creating semiconductor isolator junctions.

Once the semiconductor devices have been created, they are interconnected to form the desired electrical circuits. Interconnecting involves creating metal interconnecting wires isolated by dielectric layers. As the number of interconnect levels has increased substantially, the timing delay in the wiring has prompted a change in wiring material from aluminum to copper. With the increase in interconnect levels, planarization of previous layers ensures a flat surface prior to subsequent lithography. Without planarization, the interconnect levels can become increasingly crooked and dimpled, and may extend outside the depth of focus of available lithography. Chemical-mechanical planarization achieves the smooth surfaces desired for proper performance. Wire bond traces may be nickel/gold plated and then polished as part of the fabrication process.

Chemical etch back processes can be problematic and design limited. Long tails on interconnects may remain after chemical etching back and may extend beyond a minimum size specified for the trace. The long tails may not meet electrical performance specifications. The long tails increase insertion loss and reflection loss and increase cross talk noise on an electrical signal. The electrical effects may start to occur when the tail is longer than 500 μm, for example. Aspects discussed below provide a laser etch back process for removal of long tails and improving electrical performance for wire bond and surface mount device (SMD) pads on semiconductor devices.

Various aspects of the present disclosure provide dry etch back substrate interconnections. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. As further described, the term “laminate” may refer to a multilayer sheet to enable packaging of an IC device. The terms “substrate,” “wafer,” and “laminate” may be used interchangeably. Similarly, the terms “chip,” “chiplet,” and “die” may be used interchangeably.

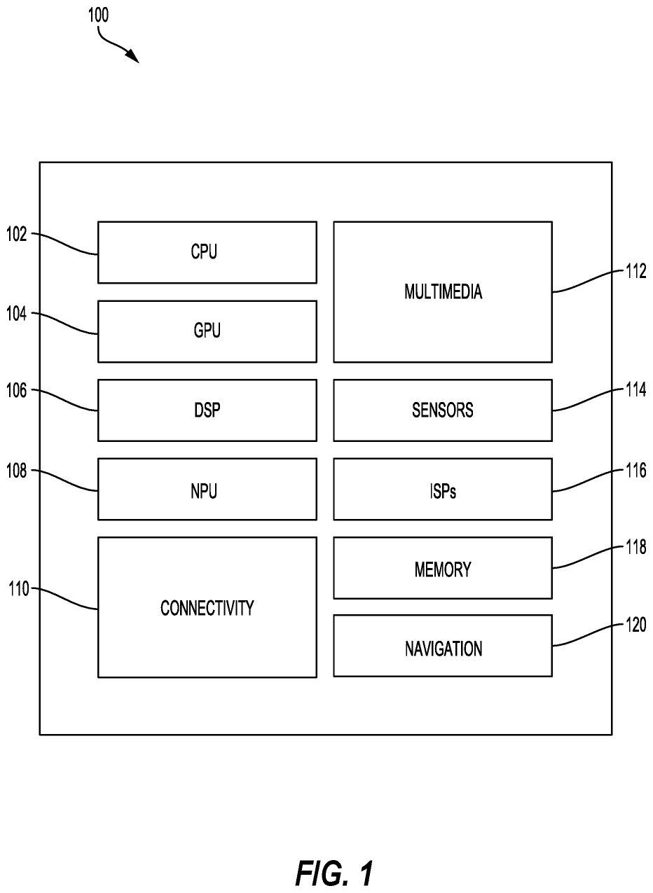

FIG. 1 illustrates an example implementation of a host system-on-a-chip (SoC) 100, which includes dry etch back substrate interconnections, in accordance with aspects of the present disclosure. The host SoC 100 includes processing blocks tailored to specific functions, such as a connectivity block 110. The connectivity block 110 may include fifth generation (5G) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU 108, and the multi-media engine 112 support various functions such as video, audio, graphics, gaming, artificial networks, and the like. Each processor core of the multi-core CPU 102 may be a reduced instruction set computing (RISC) machine, an advanced RISC machine (ARM), a microprocessor, or some other type of processor. The NPU 108 may be based on an ARM instruction set.

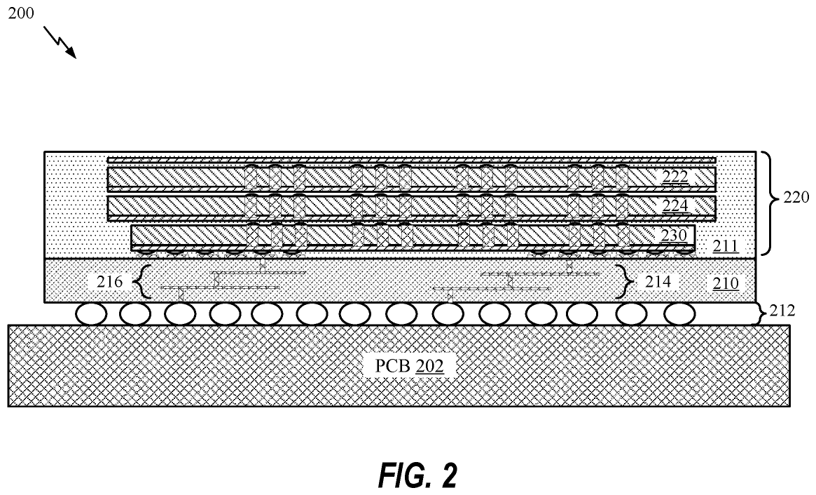

FIG. 2 shows a cross-sectional view illustrating a stacked IC package 200 of the SoC 100 of FIG. 1. Representatively, the stacked IC package 200 includes a printed circuit board (PCB) 202 connected to a package substrate 210 with interconnects 212. In this configuration, the package substrate 210 includes conductive layers 214 and 216. Above the package substrate 210 is a 3D chip stack 220, including stacked dies 222, 224, and 230, encapsulated by mold compound 211. In one aspect of the present disclosure, the die 230 is the SoC 100 of FIG. 1.

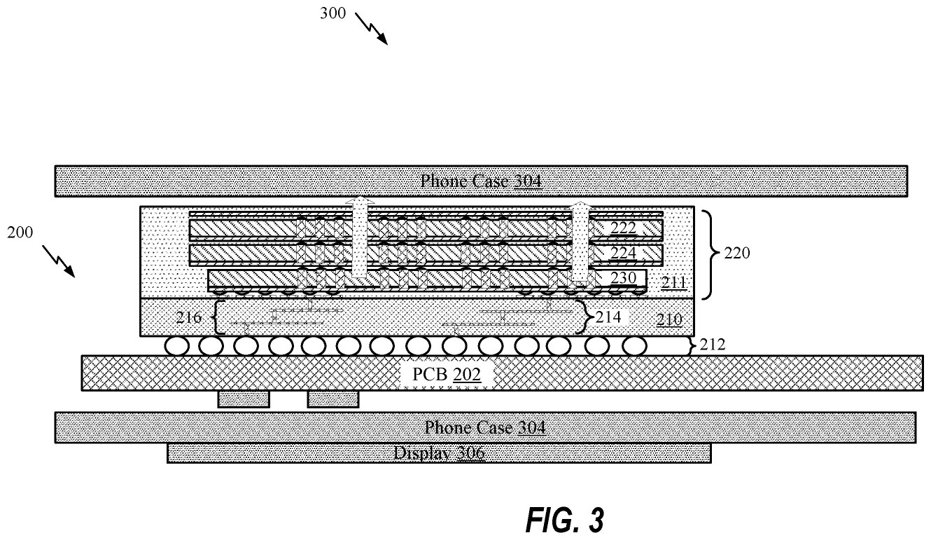

FIG. 3 shows a cross-sectional view illustrating the stacked IC package 200 of FIG. 2, incorporated into a wireless device 300, according to one aspect of the present disclosure. As described, the wireless device 300 may include, but is not limited to, a smartphone, tablet, handheld device, or other limited form factor device configured for 5G communications. Representatively, the stacked IC package 200 is within a phone case 304, including a display 306. In this configuration, a system-on-a-chip (SoC) incorporates dry etch back substrate interconnections.

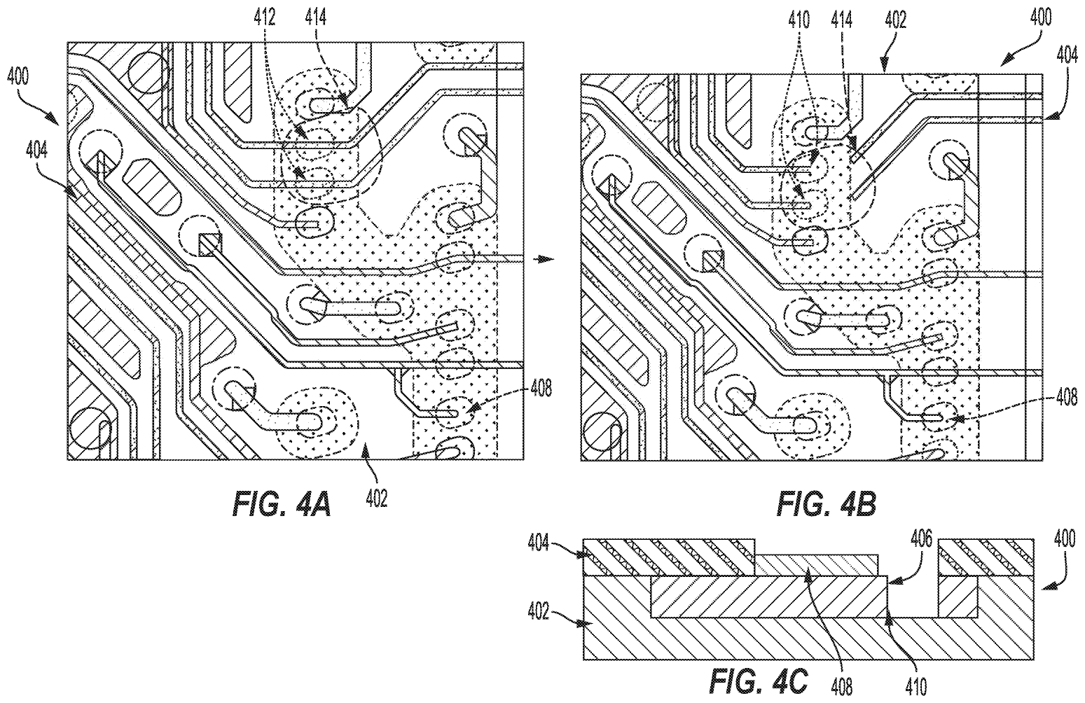

FIG. 4A shows a top view of a wire bond trace before laser etching, in accordance with various aspects of the present disclosure. A semiconductor assembly 400 is formed with dielectric material 402 in which long traces 406 (shown in the side view of FIG. 4C) are formed. The long traces 406 are covered with a photosensitive resist 404 during fabrication. Wire bond pads 408, which may be nickel/gold (Ni/Au), are formed on top of the long traces 406. It is noted that other materials may be used. When the nickel/gold wire bond pads 408 are added during the semiconductor fabrication process, a plating line delineates areas that will be chemically etched during the next phase of the fabrication process. After the chemical etch back is performed, long tails 412, shown in the dashed area 414, may remain. If the long tails 412 are greater than 250-500 μm, for example, they can adversely affect electrical performance, possibly by increasing insertion loss, increasing reflection losses, and increasing cross talk noise. FIG. 4A shows long tails 412 remaining in the dashed area 414 after removal of the photosensitive resist 404 after chemical etch back. According to aspects of the present disclosure, the long tails 412 within the dashed area 414 will be laser etched back to remove the long tails 412.

FIG. 4B shows a top view of a wire bond trace after laser etching, in accordance with various aspects of the present disclosure. The laser etch back is performed on the long tails 412 in the dashed area 414, removing the long tails 412 and producing laser etched back tails 410. Other aspects of the semiconductor assembly 400 are unaffected by the laser etch back of the long tails 412. The dielectric material 402, remaining photosensitive resist 404, long traces 406, and wire bond pads 408 are not altered during the laser etch back process.

FIG. 4C shows a side view of a wire bond trace after laser etch back, in accordance with various aspects of the present disclosure. The semiconductor assembly 400 includes dielectric material 402 with photosensitive resist 404 on top of the dielectric material 402. The long trace 406 is within a cavity formed in the dielectric material 402. On top of the long trace 406 is a nickel/gold wire bond pad 408. The area of the laser etched back tails 410 shows how the laser etch back operation cuts the long trace 406, removing the long tail 412 (as shown in FIG. 4A).

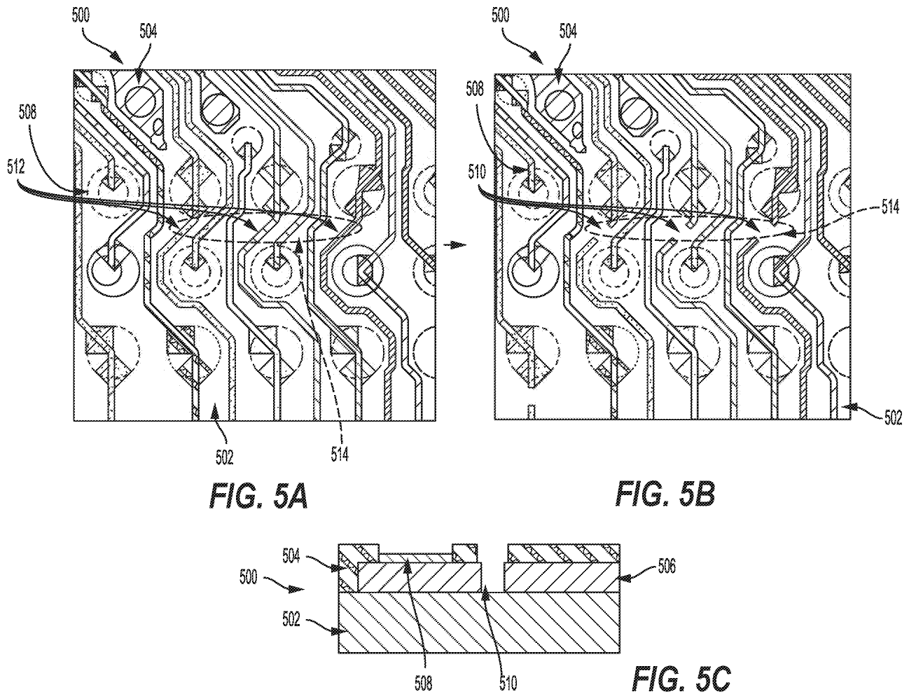

FIG. 5A shows a top view of a surface mount device (SMD) trace before laser etch back, in accordance with various aspects of the present disclosure. A semiconductor assembly 500 is formed with dielectric material 502 and a long trace 506 (as shown in FIG. 5C) on top of the dielectric material 502. A photosensitive resist 504 covers the long traces 506 during fabrication. The photosensitive resist 504 is chemically removed before SMD pads 508, are applied. The SMD pads 508 may be nickel/gold, however, other materials may be used. SMD pads are used with surface mount devices (SMDs) that are soldered to the SMD pad patterns formed on a surface of a semiconductor device. A dashed area 514 shows long tails 512 from the long traces 506 formed between some of the SMD pads 508. According to aspects of the present disclosure, the unwanted long tails 512 are etched back in selected areas using a laser during a laser etch back operation.

FIG. 5B shows a top view of a surface mount device (SMD) pad trace after laser etching, in accordance with various aspects of the present disclosure. The laser etch back is performed a slight distance away from the SMD pad 508 so that the SMD pad 508 is not affected. Other aspects of the semiconductor assembly 500 are unaffected by the laser etch back of the long tails 512. The dielectric material 502, remaining photosensitive resist 504, traces 506, and SMD pads 508 are not altered during the laser etch back process. After laser etch back, the dashed area 514 shows laser etched back long tails 510.

FIG. 5C shows a side view of a surface mount device (SMD) pad trace after laser etching, in accordance with various aspects of the present disclosure. FIG. 5C shows the layers of the semiconductor assembly 500. A dielectric material 502 has a long trace 506 between SMD pads 508. The long trace 506 is topped by a layer of photosensitive resist 504. The photosensitive resist 504 has been removed from portions of the top layer of the long trace 506 in preparation for plating the nickel/gold SMD pad 508. The photosensitive resist 504 material covers portions of the long trace 506 and may cover areas of the dielectric material 502 where there are no traces. The nickel/gold SMD pad 508 is shown after laser etch back, with the laser etch back located safely away from the nickel/gold SMD pad 508, so as not to adversely affect SMD pad interconnectivity.

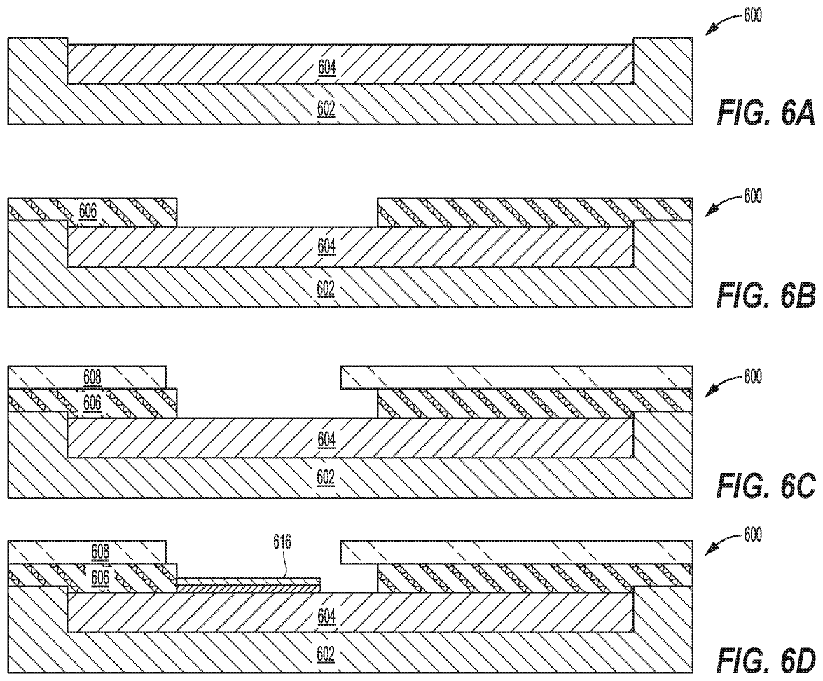

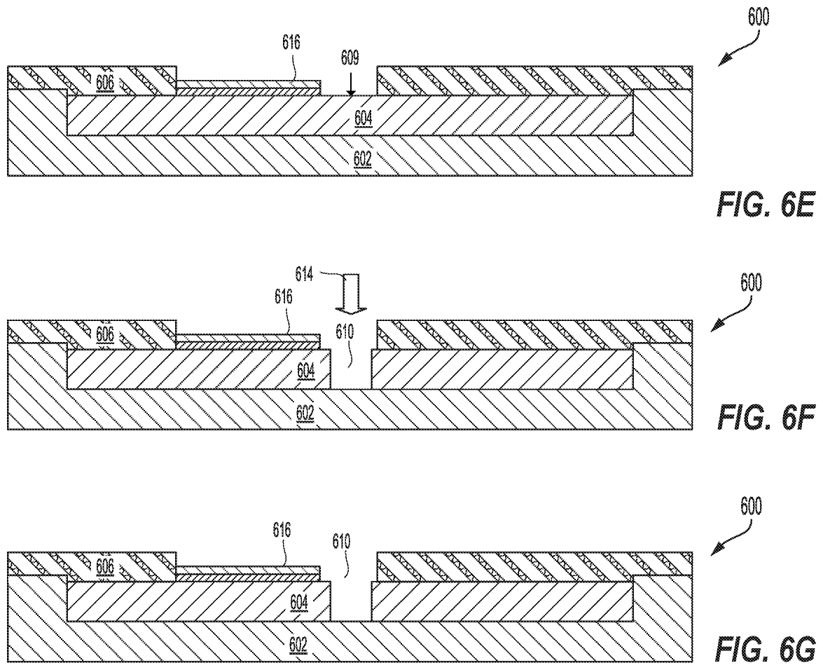

FIGS. 6A-6G are cross-sectional diagrams illustrating a manufacturing process flow for a wire bond trace, in accordance with aspects of the present disclosure. FIG. 6A shows a cross section of a wafer used in fabricating a semiconductor assembly 600. Wafers used in semiconductor fabrication may be pure silicon or a low K insulator that is grown into a non-crystalline cylindrical ingot that may be up to 300 mm in diameter. These ingots are sliced into wafers that may be about 0.75 mm thick, for example, which are then polished to provide a flat and regular surface. In the example of FIG. 6A, a dielectric material 602 forms the wafer on which the semiconductor assembly 600 will be fabricated. FIG. 6A also shows the formation of long traces 604 in the dielectric material 602. During deposition, a conductive material is grown, coated, or transferred onto the wafer to provide the long traces 604 for electrical circuits. Outer layer patterning may use physical vapor deposition, chemical vapor deposition, electrochemical deposition, molecular beam epitaxy, and atomic layer deposition. During deposition, an oxide layer is formed by thermal oxidation or local oxidation of silicon.

After deposition, removal is performed. Removal is any process that removes material from the wafer, such as etching processes or planarization. Etching may be either wet or dry and planarization may be chemical-mechanical planarization. Once planarization is complete, patterning begins. The wafer is also referred to as a dielectric material 602 at this point in the fabrication process.

Outer layer patterning is shown in FIG. 6B, which provides a side view of the wafer during the process steps. The dielectric material 602 has a long trace 604 embedded within the dielectric material 602. Patterning is the shaping or altering of deposited materials and is known as lithography. In lithography, the wafer is coated with a photosensitive resist 606 shown in FIG. 6B. After coating the dielectric material 602 with the photosensitive resist 606, a stepper machine focuses, aligns, and removes a mask, exposing selected portions of the dielectric material 602 beneath to short wavelength light. The exposed regions are then washed with a developer solution. The lithography process may also be a semi-additive process. After etching, the remaining photosensitive resist 606 is removed by plasma ashing.

At this point in the fabrication process, the wafer has a dielectric material 602 with long traces 604 embedded in the substrate. The next processing step is masking for conductive plating, such as nickel/gold plating, that is shown in FIG. 6C. A nickel/gold plating mask 608 is placed and aligned, so that only selected portions of the long trace 604 receive the nickel/gold surface plating 616, shown in FIG. 6D. After the nickel/gold surface plating 616 is applied, the wafer appears as shown in FIG. 6D.

After nickel/gold surface plating 616, the nickel/gold plating mask 608 is removed, and the wafer appears as shown in FIG. 6E. The mask removal process uses a dry film process and leaves the long tails 609. The long tails 609 are present after the dry film or photosensitive resist 606 removal. The etch back line for the dry film removal results in the long tails 609. The long tails 609 are removed as illustrated in FIG. 6F, using a laser 614 to etch back, with the laser cutting the long tails 609, producing the laser etched back tails 610. In one example, the laser etched back tails 610 are five microns or less. FIG. 6F shows a side view of the location and effect of the laser etch back, which cuts the long trace 604 to remove the long tails 609. Following the laser etch back process, the wafer is then cleaned to remove debris to create the finished semiconductor assembly 600, shown in FIG. 6G.

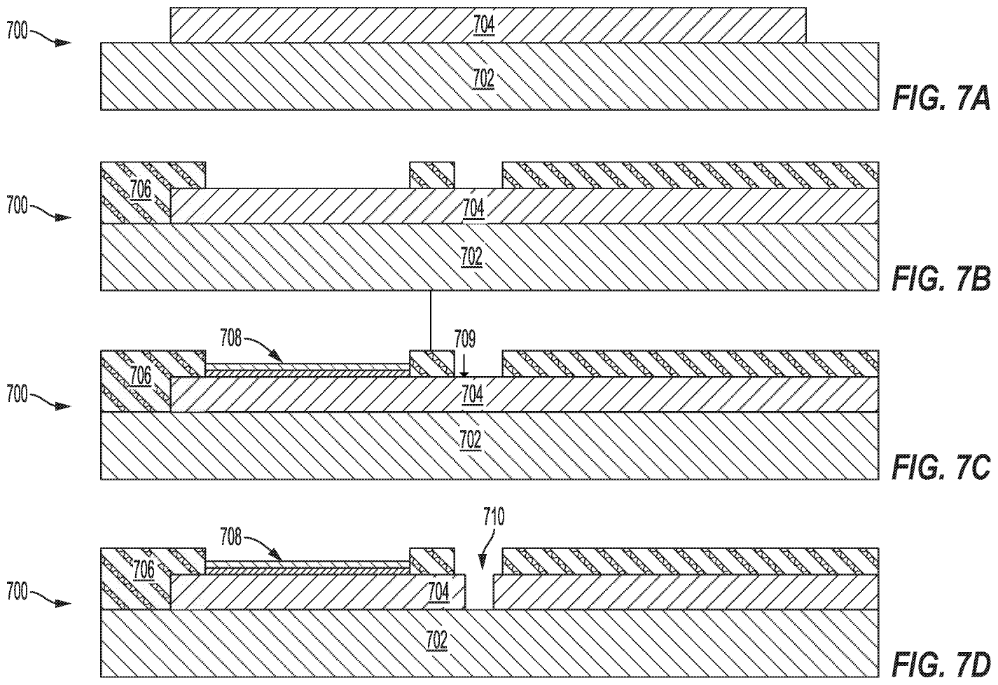

FIGS. 7A-7D are cross-sectional diagrams illustrating a manufacturing process flow for a surface mount device (SMD) pad trace, in accordance with aspects of the present disclosure. A semiconductor assembly 700 may use a wafer similar to that described with respect to the wafer used in a wire bond fabrication process, such as described with respect to FIGS. 6A-6G. The wafer may be used with surface mounted devices that use surface mount device array patterns or regions to mount devices. FIG. 7A shows the process of forming long SMD pad traces 704 on top of a dielectric material 702. FIG. 7A illustrates the outer layer patterning applied on top of the dielectric material 702. This outer layer patterning produces the long SMD pad traces 704.

FIG. 7B shows portions of the dielectric material 702 and portions of the long (SMD) pad trace 704 coated with photosensitive resist 706. The photosensitive resist 706 is developed and then removed, leaving the wafer in the condition shown in FIG. 7B with portions of the long SMD pad trace 704 coated with developed photosensitive resist 706. The lithography process may be a semi-additive process. After etching, the remaining photosensitive resist 706 is removed by plasma ashing.

At this point in the fabrication process, the dielectric material 702 has a substrate with SMD pads formed in an area on top of the long SMD pad traces 704 on the substrate. The next processing step is shown in FIG. 7C, where nickel/gold plating occurs to create nickel/gold SMD pads 708. Nickel/gold SMD pads 708 are placed in a surface mount device grid array pattern on top of the long SMD pad trace 704. FIG. 7C shows the nickel/gold SMD pads 708 after plating. The long SMD pad trace 704 between the nickel/gold SMD pads 708 is present after the dry film removal. An undesirable long tail 709 is present.

FIG. 7D is a cross-sectional diagram illustrating a step in a manufacturing process flow for a surface mount device (SMD) pad trace, in accordance with aspects of the present disclosure. The semiconductor assembly 700 is shown after laser etch back 710 to remove the long tail 709. The wafer has the long SMD pad trace 704 on the surface. In some areas, the photosensitive resist 706 is on top of the long SMD pad trace 704. As shown in FIG. 7D, a laser etch back 710 of the long SMD pad trace 704 is performed adjacent to the SMD pad region, to remove the long tail 709 without severing or damaging the interconnections between the nickel/gold SMD pads 708. Following the laser etch back 710 process the wafer is then cleaned to remove debris.

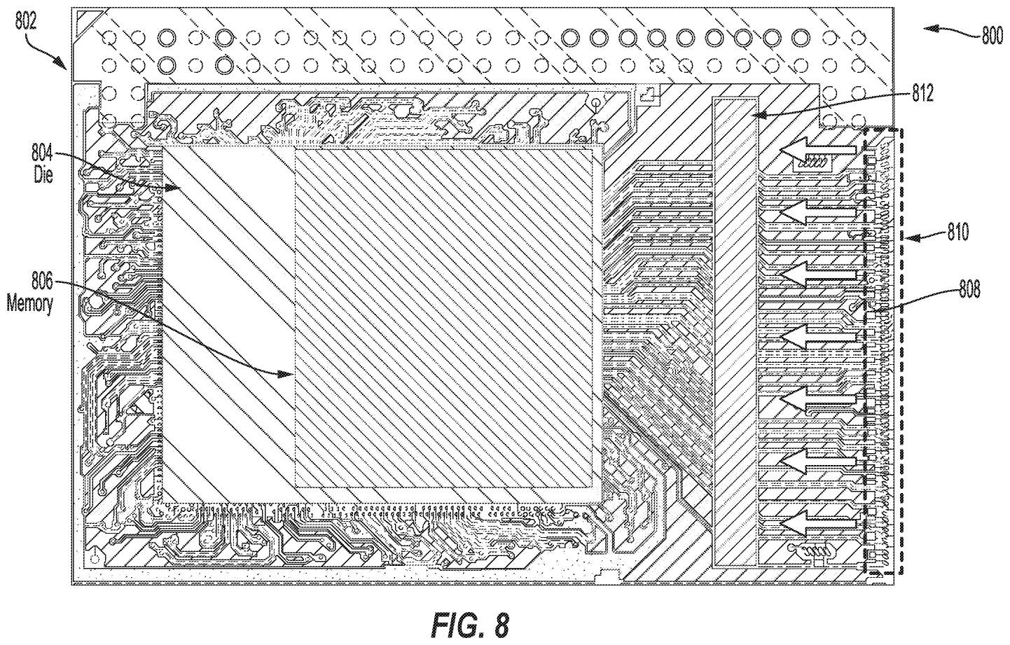

FIG. 8 shows a top view of a logic die and a memory package, incorporating a reduction in path length, in accordance with various aspects of the present disclosure. A semiconductor assembly 800 includes a substrate 802 having traces and interconnections and a die 804 with memory 806 mounted on top of die 804. The semiconductor assembly 800 also includes wire bond pads, shown in a current location, at a right edge 810 of the substrate 802. The wire bond pads 808 are placed on the substrate 802 near the die 804 and memory 806. Placing the wire bond pads 808 on the substrate 802 adjacent to the die 804 and memory 806 shortens the path length and provides better inductance. The laser etch back process described above allows moving the wire bond pads 808 from the right edge 810 of the substrate 802 closer to the die, to a new location 812, containing the devices using those traces. The new location 812 is closer to the die 804, shortening the path length.

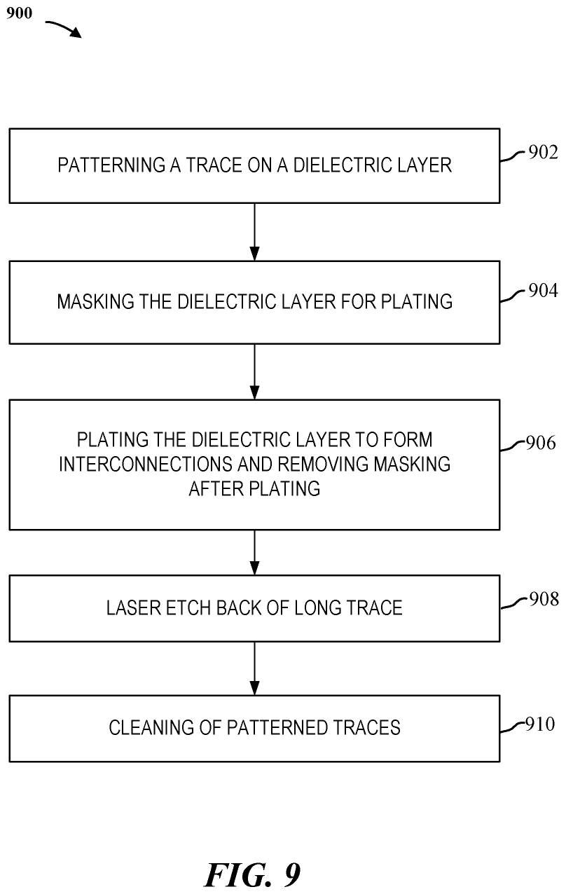

FIG. 9 is a flow diagram of a process 900 for laser etching a wire bond trace, in accordance with aspects of the present disclosure. In block 902 patterning a trace on a dielectric layer occurs. As seen in FIG. 6A, a material is grown, coated or transferred onto the wafer to provide long traces 604 for electrical circuits. During deposition, a conductive material is grown, coated, or transferred onto the wafer to provide the long traces 604 for electrical circuits. Outer layer patterning may use physical vapor deposition, chemical vapor deposition, electrochemical deposition, molecular beam epitaxy, and atomic layer deposition.

In block 904, masking the dielectric layer for plating is performed. The wafer is coated with a photosensitive resist 606, as shown in FIG. 6B. After coating the dielectric material 602 with the photosensitive resist 606, a stepper machine focuses, aligns, and removes a mask, exposing selected portions of the dielectric material 602 beneath to short wavelength light. The exposed regions are then washed with a developer solution.

In block 906, plating the dielectric layer to form interconnections and removing masking after plating occurs. As shown in FIG. 6C, a nickel/gold plating mask 608 is placed and aligned, so that only selected portions of the long trace 604 receive the nickel/gold surface plating 616. After nickel/gold surface plating 616, the nickel/gold plating mask 608 is removed. FIG. 6D shows the dielectric material 602 with the nickel/gold plating mask 608 removed after plating to form the interconnections. The mask removal process uses a dry film process and leaves the long traces 604 with long tails 609. FIG. 6E shows the long tails 609 are present after the dry film or photosensitive resist 606 removal.

In block 908, laser etch back of long trace occurs. The etch back line for the dry film removal results in removal of the long tails 609. The long tails 609 are removed as illustrated in FIG. 6F, using a laser 614 to etch back, with the laser cutting the long traces 604, producing the laser etched back tails 610. In block 910, cleaning of patterned traces is performed. FIG. 6G shows the finished semiconductor assembly 600 after laser etch back and cleaning.

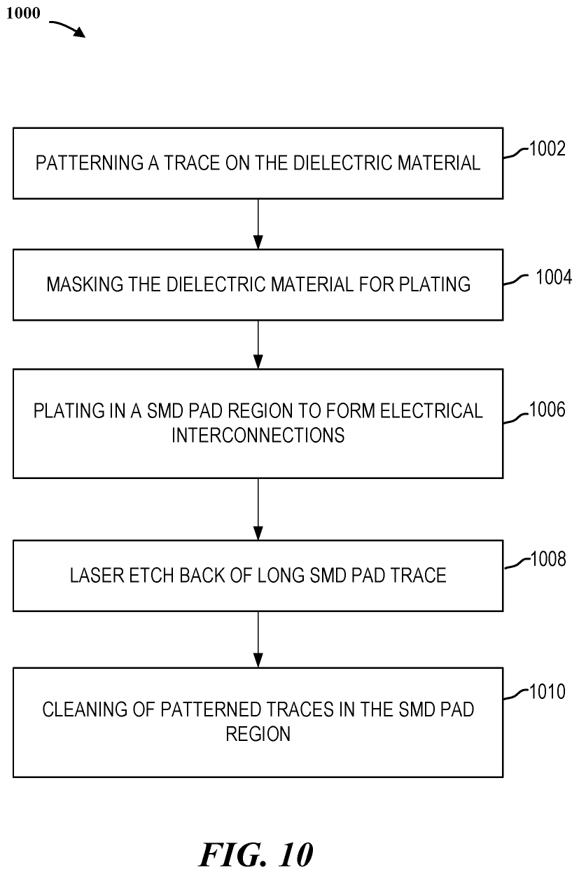

FIG. 10 is a flow diagram of a process 1000 for laser etching a surface mount device (SMD) pad trace, in accordance with aspects of the present disclosure. The process 1000 begins in block 1002, with patterning a trace on the dielectric material. FIG. 7A shows the process of forming long SMD pad traces 704 on top of the dielectric material 702. During deposition, a material is grown, coated, or transferred onto the wafer to provide the long SMD pad traces 704 for electrical circuits. The wafer may also be known as the dielectric material 702. The outer layer patterning process may use physical vapor deposition, chemical vapor deposition, electrochemical deposition, molecular beam epitaxy, and atomic layer deposition.

Next, in block 1004, the dielectric material is masked for plating. This processing step is shown in FIG. 7B, and applies the masking for nickel/gold SMD pads 708. The plating mask is placed and aligned so that the nickel/gold SMD pads 708 and interconnections receive the nickel/gold SMD pads 708 surface finish.

In block 1006, the dielectric layer is plated in a SMD pad region to form electrical interconnections. FIG. 7C shows the nickel/gold ball SMD 708 after plating. In block 1008 a laser etch back of the long SMD pad trace adjacent to the ball pad region is performed. As shown in FIG. 7D, the laser etch back 710 of the long SMD pad trace 704 is performed adjacent to the SMD pad region, to remove the long tail 709 without severing or damaging the interconnections between the nickel/gold SMD pads 708.

In block 1010, cleaning of patterned traces in the SMD pad region is performed. As shown in FIG. 7D, following the laser etch back 710 process, the wafer is then cleaned to remove debris. After laser etch back and cleaning the wafer assembly appears as shown in FIG. 7D.

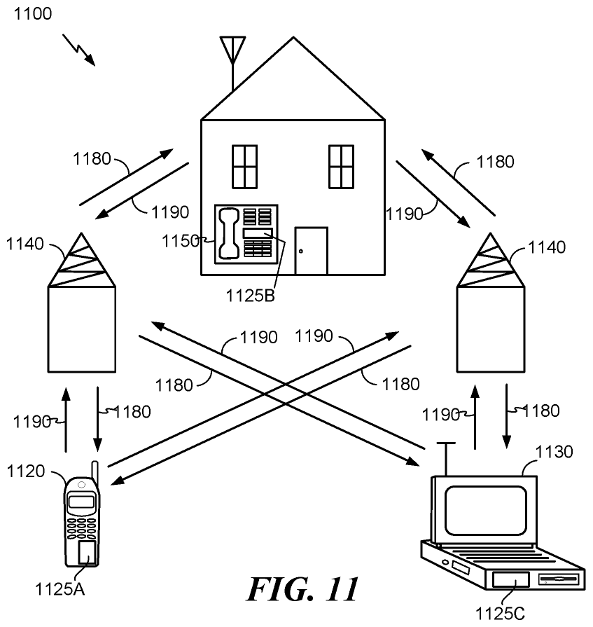

FIG. 11 is a block diagram showing an exemplary wireless communications system in which a configuration of the disclosure may be advantageously employed. For purposes of illustration, FIG. 11 shows three remote units 1120, 1130, and 1150, and two base stations 1140. It will be recognized that wireless communications systems may have many more remote units and base stations. Remote units 1120, 1130, and 1150 include IC devices 1125A, 1125B, and 1125C that include the disclosed dry etch back substrate design in a 5G semiconductor device. It will be recognized that other devices may also include the disclosed wireless device with a dry etch back substrate design, such as the base stations, switching devices, and network equipment. FIG. 11 shows forward link signals 1180 from the base stations 1140 to the remote units 1120, 1130, and 1150, and reverse link signals 1190 from the remote units 1120, 1130, and 1160 to base stations 1140.

In FIG. 11, remote unit 1120 is shown as a mobile telephone, remote unit 1130 is shown as a portable computer, and remote unit 1150 is shown as a fixed location remote unit in a wireless local loop system. For example, a remote unit may be a mobile phone, a hand-held personal communications systems (PCS) unit, a portable data unit such as a personal digital assistant (PDA), a GPS enabled device, a navigation device, a set top box, a music player, a video player, an entertainment unit, a fixed location data unit such as meter reading equipment, or other communications device that stores or retrieves data or computer instructions, or combinations thereof. Although FIG. 11 illustrates remote units according to the aspects of the present disclosure, the disclosure is not limited to these exemplary illustrated units. Aspects of the disclosure may be suitably employed in many devices, which include the wireless device with the dry etch back substrate design.

The foregoing disclosure provides illustration and description, but is not intended to be exhaustive or to limit the aspects to the precise form disclosed. Modifications and variations may be made in light of the above disclosure or may be acquired from practice of the aspects.

As used herein, the term “component” is intended to be broadly construed as hardware, firmware, and/or a combination of hardware and software. As used herein, a processor is implemented in hardware, firmware, and/or a combination of hardware and software.

Some aspects are described in this document in connection with thresholds. As used in this document, satisfying a threshold may, depending on the context, refer to a value being greater than the threshold, greater than or equal to the threshold, less than the threshold, less than or equal to the threshold, equal to the threshold, not equal to the threshold, and/or the like.

It will be apparent that systems and/or methods described in this document may be implemented in different forms of hardware, firmware, and/or a combination of hardware and software. The actual specialized control hardware or software code used to implement these systems and/or methods is not limiting of the aspects. Thus, the operation and behavior of the systems and/or methods were described in this document without reference to specific software code—it being understood that software and hardware can be designed to implement the systems and/or methods based, at least in part, on the description in this document.

Even though particular combinations of features are recited in the claims and/or disclosed in the specification, these combinations are not intended to limit the disclosure of various aspects. In fact, many of these features may be combined in ways not specifically recited in the claims and/or disclosed in the specification. Although each dependent claim listed below may directly depend on only one claim, the disclosure of various aspects includes each dependent claim in combination with every other claim in the claim set. A phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

No element, act, or instruction used in this document should be construed as critical or essential unless explicitly described as such. Also, as used in this document, the articles “a” and “an” are intended to include one or more items, and may be used interchangeably with “one or more.” Furthermore, as used in this document, the terms “set” and “group” are intended to include one or more items (e.g., related items, unrelated items, a combination of related and unrelated items, and/or the like), and may be used interchangeably with “one or more.” Where only one item is intended, the phrase “only one” or similar language is used. Also, as used in this document, the terms “has,” “have,” “having,” and/or the like are intended to be open-ended terms. Further, the phrase “based on” is intended to mean “based, at least in part, on” unless explicitly stated otherwise.

What is claimed is:

1. A method of forming electrical interconnections, comprising:
patterning a trace on a dielectric layer;
masking the dielectric layer for plating;
plating the dielectric layer to form electrical interconnections and then removing the masking after plating;
performing a laser etch back of the trace after removing the masking, in which the laser etch back removes tails on the trace; and
cleaning the patterned traces and the dielectric layer after performing the laser etch back.

2. The method of claim 1, in which the trace forms a wire bond interconnection.

3. The method of claim 1, in which plating the dielectric layer to form electrical interconnections forms the electrical interconnections in a surface mount device (SMD) pad region.

4. The method of claim 1, in which the laser etch back of the trace is performed adjacent to a surface mount device (SMD) pad region.

5. The method of claim 1, in which patterning the trace on the dielectric layer embeds the trace in the dielectric layer.

6. The method of claim 1, in which patterning the trace on the dielectric layer adds the trace to a top surface of the dielectric layer.

7. The method of claim 1, in which the plating is a nickel/gold alloy.

8. The method of claim 1, further comprising placing a set of wire bond pads adjacent to a surface mount device (SMD) pad die pattern.

9. An electronic device, comprising:
a dielectric layer having a trace patterned on the dielectric layer;
a plating material on the trace electrically coupled to the trace; and
a long tail extending from the trace, and configured to be laser etched back based on length.

10. The electronic device of claim 9, in which the trace patterned on the dielectric layer is configured to form a wire bond.

11. The electronic device of claim 9, in which the trace patterned on the dielectric layer is configured to form electrical interconnections in a surface mount device (SMD) pad region.

12. The electronic device of claim 9, in which the trace is embedded within the dielectric layer.

13. The electronic device of claim 9, in which the trace is placed on the dielectric layer.

14. The electronic device of claim 9, in which the trace is configured to be laser etched back on a wire bond.

15. The electronic device of claim 9, in which the trace is configured to be laser etched back adjacent to a surface mount device (SMD) pad region.

16. An electrical interconnection, comprising:
a dielectric layer having a trace patterned on the dielectric layer, the trace configured to form an electrical interconnection;
means for forming electrical interconnections with the trace; and
a long tail extending from the trace and configured to be laser etched back based on length.

17. The electrical interconnection of claim 16, in which the trace patterned on the dielectric layer is configured to form a wire bond.

18. The electrical interconnection of claim 16, in which the trace patterned on the dielectric layer is configured to form the electrical interconnections in a surface mount device (SMD) pad region.

19. The electrical interconnection of claim 16, in which the trace is embedded within the dielectric layer.

20. The electrical interconnection of claim 16, in which the trace is placed on the dielectric layer.
